(19) United States
(12) Patent Application Publication
(10) Pub. No.: US 2024/0322071 A1
(43) Pub. Date: Sep. 26, 2024

(54) LIGHT-EMITTING DIODE MODULE, PREPARATION METHOD THEREFOR, AND TRANSFER METHOD FOR A LIGHT-EMITTING ELEMENT

(71) Applicant: Tianma Advanced Display Technology Institute (Xiamen) Co., Ltd., Xiamen (CN)

(72) Inventors: Jingtao GUO, Xiamen (CN); Canyuan ZHANG, Xiamen (CN); Qiang GU, Xiamen (CN); Bo ZHOU, Xiamen (CN)

(73) Assignee: Tianma Advanced Display Technology Institute (Xiamen) Co., Ltd., Xiamen (CN)

(21) Appl. No.: 18/678,523

(22) Filed: May 30, 2024

(30) Foreign Application Priority Data
Dec. 14, 2023 (CN) 202311728941.2

(51) Int. Cl. H01L 33/00; H01L 25/075

(52) U.S. Cl. CPC H01L 33/0093; H01L 25/0753

(57) ABSTRACT

Provided are a light-emitting diode module, a preparation method therefor, a transfer method for a light-emitting element, a display panel, and a display device. The light-emitting diode module includes a first substrate, a sacrificial protective layer, and multiple light-emitting elements. The first substrate has multiple first regions arranged at intervals and second regions, where a second region is located between adjacent first regions. The sacrificial protective layer is located on a side of the first substrate and at least partially located in the second region. The multiple light-emitting elements are disposed in the multiple first regions and located on the same side of the first substrate as the sacrificial protective layer.

### CROSS-REFERENCE TO RELATED APPLICATION

This application claims priority to Chinese Patent Application No. CN 202311728941.2, filed on Dec. 14, 2023, the disclosure of which is incorporated herein by reference in its entirety.

### TECHNICAL FIELD

The present application relates to the technical field of display devices and, in particular, to a light-emitting diode module, a preparation method therefor, a transfer method for a light-emitting element, a display panel, and a display device.

### BACKGROUND

The micro light-emitting diode (microLED) technology, that is, LED miniaturization and matrix technology, has good stability, a long lifespan, and an operating temperature advantage and inherits the advantages of the LED such as low power consumption, high color saturation, fast response speed, and high contrast. The microLED has higher brightness and lower power consumption so that the microLED has great application prospects.

However, the current display device using microLEDs still has problems such as a relatively low preparation yield and needs to be further improved.

### SUMMARY

Embodiments of the present application provide a display panel and a display device to improve the applicability of the display panel.

In a first aspect, an embodiment of the present application provides a light-emitting diode module. The light-emitting diode module includes a first substrate, a sacrificial protective layer, and multiple light-emitting elements. The first substrate has multiple first regions arranged at intervals and second regions, where a second region is located between adjacent first regions. The sacrificial protective layer is located on a side of the first substrate and at least partially located in the second region. The multiple light-emitting elements are disposed in the multiple first regions and located on the same side of the first substrate as the sacrificial protective layer.

In a second aspect, an embodiment of the present application provides a preparation method for a light-emitting diode module. The preparation method includes the steps described below.

A sacrificial protective material layer is formed on a side of a first substrate, where the first substrate has first regions arranged at intervals and second regions, where a second region is located between adjacent first regions, and the sacrificial protective material layer is at least partially located in the second region.

An epitaxial structure is formed on a side of the first substrate, where the epitaxial structure covers the first region and the second region.

The epitaxial structure is patterned to form a light-emitting module in the first region and a sacrificial protective layer at least partially located in the second region, where the light-emitting module includes part of film structures of a light-emitting element.

In a third aspect, an embodiment of the present application provides a transfer method for a light-emitting element. The transfer method includes the steps described below.

The light-emitting diode module in any preceding embodiment is provided.

The light-emitting element and the sacrificial protective layer are simultaneously separated from the first substrate by using a laser, and the light-emitting element and the sacrificial protective layer are transferred to a target substrate.

At least part of a structure between corresponding adjacent light-emitting elements in the sacrificial protective layer is removed.

In a fourth aspect, an embodiment of the present application provides a display panel. The display panel includes light-emitting elements transferred and formed by using the transfer method in any preceding embodiment.

In a fifth aspect, an embodiment of the present application provides a display device. The display device includes the display panel in any preceding embodiment.

### BRIEF DESCRIPTION OF DRAWINGS

To illustrate technical solutions in embodiments of the present application more clearly, the drawings used in the description of the embodiments are briefly described below. Those skilled in the art may obtain other drawings based on the drawings described below on the premise that no creative work is done.

FIG. 1 is a structural diagram of a light-emitting diode module in the related art;

FIG. 2 is an enlarged structural diagram of region P in FIG. 1;

FIG. 3 is a structural diagram of a light-emitting diode module according to an embodiment of the present application;

FIG. 4 is a structural diagram of another light-emitting diode module according to an embodiment of the present application;

FIG. 5 is a structural diagram of another light-emitting diode module according to an embodiment of the present application;

FIG. 6 is a structural diagram of another light-emitting diode module according to an embodiment of the present application;

FIG. 7 is an enlarged structural diagram of region Q in FIG. 6;

FIG. 8 is a flowchart of a preparation method for a light-emitting diode module according to an embodiment of the present application;

FIGS. 9A to 9C are structural diagrams illustrating the process of a preparation method for a light-emitting diode module according to an embodiment of the present application;

FIG. 10 is a structural diagram illustrating the process of another preparation method for a light-emitting diode module according to an embodiment of the present application;

FIG. 11 is a flowchart of another preparation method for a light-emitting diode module according to an embodiment of the present application;

FIGS. 12A and 12B are structural diagrams illustrating the process of another preparation method for a light-emitting diode module according to an embodiment of the present application;

FIG. 13 is a flowchart of another preparation method for a light-emitting diode module according to an embodiment of the present application;

FIG. 14 is a structural diagram illustrating the process of another preparation method for a light-emitting diode module according to an embodiment of the present application;

FIG. 15 is a flowchart of a transfer method for a light-emitting element according to an embodiment of the present application;

FIGS. 16A to 16C are structural diagrams illustrating the process of a transfer method for a light-emitting element according to an embodiment of the present application;

FIG. 17 is a flowchart of another transfer method for a light-emitting element according to an embodiment of the present application;

FIG. 18 is a structural diagram illustrating the process of another transfer method for a light-emitting element according to an embodiment of the present application;

FIG. 19 is a flowchart of another transfer method for a light-emitting element according to an embodiment of the present application;

FIG. 20 is a structural diagram illustrating the process of another transfer method for a light-emitting element according to an embodiment of the present application;

FIG. 21 is a structural diagram of a display panel according to an embodiment of the present application; and

FIG. 22 is a structural diagram of a display panel according to an embodiment of the present application.

### REFERENCE LIST

100 light-emitting diode module
200 display panel
300 display device
10 first substrate
20 sacrificial protective layer
21 sacrificial part
22 buffer part
30 light-emitting element
31 first semiconductor layer
32 light-emitting layer
33 second semiconductor layer
34 electrode
40 insulating layer
41 first part
411 first sub-part
412 second sub-part
42 second part
50 target substrate
51 second substrate
52 adhesive layer
61 light-emitting device
62 substrate
63 buffer layer
20 sacrificial protective material layer
21′ initial-state sacrificial part
3 epitaxial structure
30′ light-emitting module
A1 first region
A2 second region
X thickness direction

### DETAILED DESCRIPTION

Features and example embodiments in various aspects of the present application are described hereinafter in detail. To provide a clearer understanding of the objects, technical solutions, and advantages of the present application, the present application is further described in detail in conjunction with drawings and embodiments. It is to be understood that the embodiments set forth below are intended to illustrate and not to limit the present application. To those skilled in the art, the present application may be implemented with no need of some of these specific details. The description of the embodiments hereinafter is intended merely to provide a better understanding of the present application through examples of the present application.

It is to be noted that herein, relationship terms such as first and second are used merely for distinguishing one entity or operation from another and do not necessarily require or imply any such actual relationship or order between these entities or operations. Furthermore, the term “including”, “containing”, or any other variant thereof is intended to encompass a non-exclusive inclusion so that a process, method, article, or device that includes a series of elements not only includes the expressly listed elements but also includes other elements that are not expressly listed or are inherent to such a process, method, article, or device. In the absence of more restrictions, the elements defined by the statement “including . . . ” do not exclude the presence of additional identical elements in the process, method, article, or device that includes the elements.

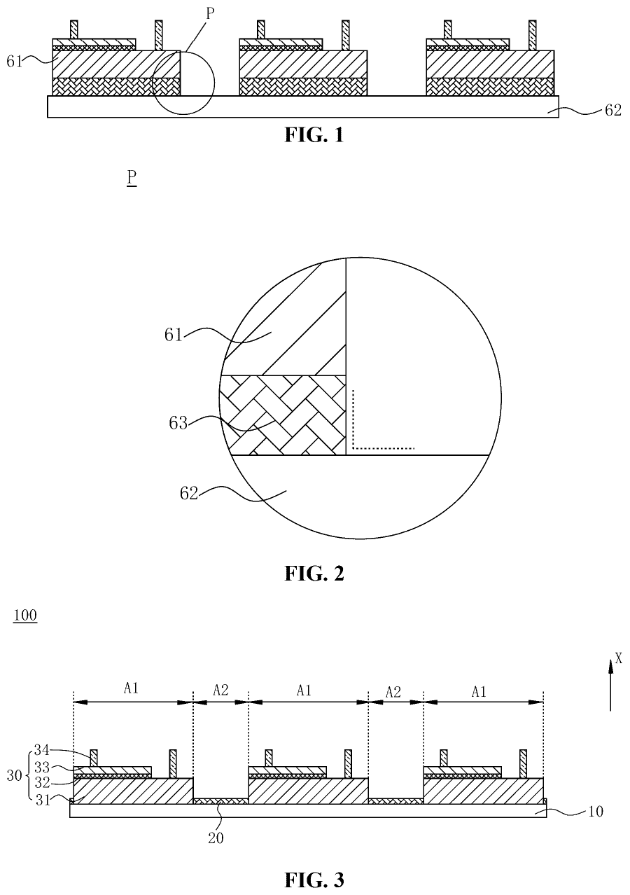

As shown in FIGS. 1 and 2, in the light-emitting diode module in the related art, the case where a light-emitting device 61 is a microLED is used as an example. The light-emitting device 61 is generally located on a side of a substrate 62, a buffer layer 63 exists between the light-emitting device 61 and the substrate 62, and multiple light-emitting devices 61 are spaced apart from each other. During the preparation process of the light-emitting diode module, film structures for forming the light-emitting device 61 in some regions are generally completely etched away, resulting in a right-angled structure or a similar right-angled structure between the buffer layer 63 and the substrate 62 as shown in FIG. 2. The right angle is illustrated by dashed lines in FIG. 2. Then during the subsequent transfer process of the light-emitting devices 61, the structure near the right-angled position is easily affected by the laser and fragmented, generating debris between adjacent light-emitting devices 61; and the debris affects the laser release accuracy, further affects the transfer accuracy corresponding to the light-emitting devices 61, and easily adversely affects the yield of the finally formed display device.

In view of this, in a first aspect, referring to FIG. 3, an embodiment of the present application provides a light-emitting diode module 100. The light-emitting diode module 100 includes a first substrate 10, a sacrificial protective layer 20, and multiple light-emitting elements 30. The first substrate 10 has multiple first regions A1 arranged at intervals and second regions A2, where a second region A2 is located between adjacent first regions A1. The sacrificial protective layer 20 is located on a side of the first substrate 10 and at least part of the sacrificial protective layer 20 is located in the second region A2. The multiple light-emitting elements 30 are disposed in the multiple first regions A1 and located on the same side of the first substrate 10 as the sacrificial protective layer 20.

The first substrate 10 may be used as a carrier for carrying film structures such as the light-emitting elements 30 and the sacrificial protective layer 20. The first substrate 10 may be a growth substrate corresponding to the light-emitting elements 30. In an embodiment, the first substrate 10 may include, but is not limited to, sapphire, silicon carbide, and silicon. During the preparation process of the light-emitting diode module 100, an epitaxial structure may be formed on the first substrate 10 through metalorganic chemical vapour deposition (MOCVD) or other methods, and then the epitaxial structure undergoes multiple processes such as etching, growth of an electrode 34, and thinning, so as to prepare and form the light-emitting elements 30 located on the first substrate 10.

The specific structure of the light-emitting element 30 is not limited to the embodiment of the present application. In an embodiment, in addition to two electrodes 34, a light-emitting structure may further include a first semiconductor layer 31, a light-emitting layer 32, and a second semiconductor layer 33 that are stacked in a direction away from the first substrate 10. Further, the first semiconductor layer 31 includes, for example, an N-type semiconductor layer, the light-emitting layer 32 includes, for example, a multiple quantum well (MWQ) structure, and the second semiconductor layer 33 includes, for example, a P-type semiconductor layer, but is not limited thereto.

The first substrate 10 has multiple first regions A1 arranged at intervals and second regions A2, where a second region A2 is located between adjacent first regions A1. The multiple first regions A1 may be arranged side by side along a single direction, or the multiple first regions A1 may be arranged side by side along different directions, where the areas corresponding to different first regions A1 may be the same or different.

The light-emitting element 30 is disposed in the first region A1, that is, the second region A2 corresponds to a region on the first substrate 10 where the light-emitting element 30 is not disposed. It can be known from the above that in the related art, other film structures except the first substrate 10 in the second region A2 of the light-emitting diode module 100 need to be completely etched away, resulting in a right angle at the junction of the first region A1 and the second region A2. Therefore, during the transfer process of the light-emitting elements 30, the structure near the right-angled position is prone to fragmentation, and debris is generated in the second region A2, affecting the transfer accuracy.

In the embodiment of the present application, other film structures except the first substrate 10 in the second region A2 of the light-emitting diode module 100 are not completely etched away, the sacrificial protective layer 20 is at least partially located in the second region A2, the sacrificial protective layer 20 may fit the first substrate 10, and the sacrificial protective layer 20 and the light-emitting element 30 are located on the same side of the first substrate 10 so that during the preparation process of the light-emitting diode module 100, the first substrate 10 is provided with the film structures on the same side of both the first region A1 and the second region A2, and the right-angled structure or similar right-angled structure is not formed at the junction of the first region A1 and the second region A2. Further, during the subsequent transfer process of the light-emitting elements 30, since no right-angled structure exists, the risk of debris can be reduced so that the laser transfer process can be prevented from being affected by the debris, which is conducive to improving the transfer accuracy of the light-emitting elements 30.

The material composition and the specific position and shape of the sacrificial protective layer 20 are not limited in the embodiments of the present application. In an embodiment, the sacrificial protective layer 20 may be located only in the second region A2, or the sacrificial protective layer 20 may be partially located in the second region A2 and partially located in the first region A1. In addition, in a thickness direction X of the first substrate 10, the sacrificial protective layer 20 may be disposed in the same layer as part of the film structures in the light-emitting element 30, or the light-emitting element 30 may be completely located on a side of the sacrificial protective layer 20 facing away from the first substrate 10.

To sum up, in the embodiment of the present application, the sacrificial protective layer 20 is added in the light-emitting diode module 100 and at least partially located in the second region A2 so that the first substrate 10 is provided with the film structure on the same side of the first region A1 and the second region A2, and the right-angled structure or similar right-angled structure is not formed at the junction of the first region A1 and the second region A2, which is conducive to reducing the risk of generating debris, improving the transfer accuracy corresponding to the subsequent transfer process of the light-emitting elements 30, and improving the preparation yield of the finally formed display device.

In addition, during the transfer process of the light-emitting elements 30, the sacrificial protective layer 20 is transferred together with the light-emitting elements 30, and at least part of the sacrificial protective layer 20 is located between adjacent light-emitting elements 30 so that during the pickling process after the subsequent transfer, the presence of the sacrificial protective layer 20 is conducive to reducing the flow of the pickling liquid to the electrode 34 in the light-emitting element 30 through the region between adjacent light-emitting elements 30, thereby protecting the electrode 34 and reducing the risk of the electrode 34 falling off or having electrical abnormalities.

In some embodiments, referring to FIG. 4, the sacrificial protective layer 20 includes a sacrificial part 21 located in the second region A2 and a buffer part 22 located in the first region A1, and the light-emitting element 30 is located on a side of the buffer part 22 facing away from the first substrate 10.

The sacrificial protective layer 20 includes at least two structures: the sacrificial part 21 and the buffer part 22. The sacrificial part 21 is located in the second region A2, and the buffer part 22 is located in the first region A1. The specific material composition of the sacrificial part 21 and the specific material composition of the buffer 22 are not limited in the embodiment of the present application. Depending on actual requirements, the sacrificial part 21 and the buffer part 22 may be made of the same material, or the sacrificial part 21 and the buffer part 22 may be made of different materials. Further, depending on actual requirements, the thickness dimension of the sacrificial part 21 may be the same as the thickness dimension of the buffer part 22, or the thickness dimension of the sacrificial part 21 may be different from the thickness dimension of the buffer part 22.

In the embodiment of the present application, the light-emitting element 30 is located on the side of the buffer part 22 facing away from the first substrate 10, and the buffer part 22 can play a buffering and protecting role for the light-emitting element 30. Further, the buffer part 22 located in the first region A1 and the sacrificial part 21 located in the second region A2 can make the sacrificial protective layer 20 have a full-surface structure, which is conducive to further isolating the light-emitting element 30 from the first substrate 10. A surface of the buffer part 22 facing the first substrate 10 and a surface of the sacrificial part 21 facing the first substrate 10 may together form a complete surface, and this surface can be located in both the first region A1 and the second region A2 so that the right-angled structure or similar right-angled structure is not formed at the junction of the first region A1 and the second region A2, thereby reducing the risk of generating debris during the subsequent transfer process of the light-emitting elements 30, which is to conducive to improving the accuracy corresponding to the subsequent transfer process of the light-emitting elements 30. Moreover, during the transfer process, the laser irradiates a side of the first substrate 10 facing away from the light-emitting element 30, and the sacrificial protective layer 20 completely isolates the first substrate 10 from the light-emitting element 30, which is conducive to reducing the adverse impact of laser irradiation on the light-emitting element 30 and improving the yield corresponding to the finally formed display device 300.

It is to be noted that the surface of the buffer part 22 facing the first substrate 10 and the surface of the sacrificial part 21 facing the first substrate 10 may together form a flat surface or may form a surface with certain undulations, and no limitation is made in the embodiments of the present application.

In addition, during the transfer process of the light-emitting elements 30, both the sacrificial part 21 and the buffer part 22 are transferred together with the light-emitting elements 30; and after the transfer, in an embodiment, only the sacrificial part 21 may be etched away so that the light-emitting elements 30 can be independent from each other. Alternatively, in an embodiment, the sacrificial part 21 and the buffer part 22 may be removed simultaneously, and no limitation is made in the embodiments of the present application.

Further, the pickling process after the light-emitting elements 30 are transferred is generally before the sacrificial part 21 is etched away. Therefore, during the pickling process, the sacrificial part 21 still exists between adjacent light-emitting elements 30 so that the sacrificial part 21 is conducive to reducing the impact of the pickling process on the electrode 34 in the light-emitting element 30 and reducing the risk of the electrode 34 falling off or having electrical abnormalities.

In some embodiments, the sacrificial part 21 and the buffer part 22 form an integral structure.

The sacrificial part 21 and the buffer part 22 form an integral structure, that is, the sacrificial part 21 and the buffer part 22 are connected to each other and include the same material so that the sacrificial part 21 and the buffer part 22 can be formed together in the same process using the same material during the preparation process of the light-emitting diode module 100.

Further, the light-emitting diode module 100 in the related art also includes the buffer part 22. Specifically, in the related art, a process needs to be provided for forming the buffer layer; however, in the subsequent process, the structure between adjacent light-emitting elements 30 in the buffer layer needs to be etched away, and only part of the structure of the buffer layer corresponding to the light-emitting elements 30 remains, thereby forming the buffer part 22. In the embodiment of the present application, the sacrificial part 21 is formed together with the buffer part 22. Specifically, during the preparation process of the light-emitting diode module 100, the sacrificial protective material is formed on a side of the first substrate 10, and a sacrificial protective material layer covers both the first region A1 and the second region A2. Then in the subsequent etching process, the structure of the sacrificial protective material layer located in the first region A1 is not etched away, thereby forming the buffer part 22, at least part of the structure of the sacrificial protective material layer located in the second region A2 remains, thereby forming the sacrificial part 21, and the buffer part 22 and the sacrificial part 21 are jointly used for forming the sacrificial protective layer 20.

It can be seen from the comparison of the preceding two preparation processes that the presence of the sacrificial protective layer 20 in the embodiment of the present application does not increase the preparation process of the light-emitting diode module 100, and the presence of the sacrificial part 21 is conducive to reducing the risk of generating debris, improving the transfer accuracy corresponding to the light-emitting elements 30, and improving the yield of the finally formed display device.

It is to be noted that in the etching process required for preparing the light-emitting diode module 100, only the epitaxial structure may be etched to form the light-emitting element 30 without etching the sacrificial protective material layer. In this case, the sacrificial protective material layer is the sacrificial protective layer 20, and the thickness of the buffer part 22 and the thickness of the sacrificial part 21 may be kept consistent. Alternatively, in the etching process, the epitaxial structure may be etched to form the light-emitting element 30, and then part of the structure in the sacrificial protective material layer located in the second region A2 is etched to form the sacrificial protective layer 20. Different from the sacrificial protective material layer, the thickness of the sacrificial protective layer 20 in the second region A2 is less than the thickness of the sacrificial protective layer 20 in the first region A1, that is, the thickness of the sacrificial part 21 is less than the thickness of the buffer part 22.

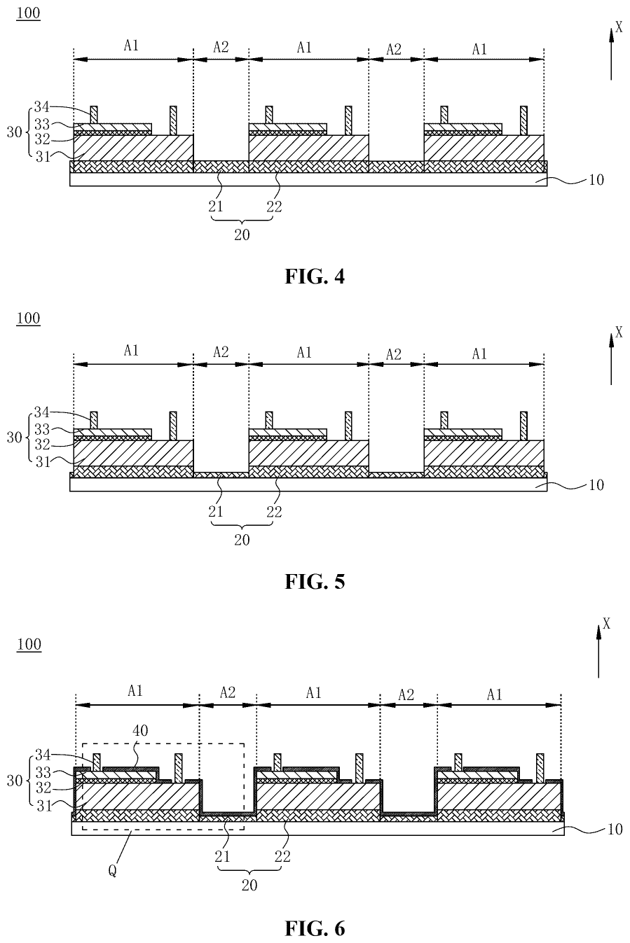

In some embodiments, referring to FIG. 5, in the thickness direction X of the first substrate 10, the dimension of the sacrificial part 21 is less than the dimension of the buffer part 22. In other words, the thickness of the sacrificial part 21 is less than the thickness of the buffer part 22.

Based on the preceding content, it can be seen that the sacrificial part 21 and the buffer part 22 may be prepared and formed together in the same process, and the second region A2 may be etched so that the thickness dimension of the sacrificial part 21 located in the second region A2 is less than the thickness dimension of the buffer part 22 located in the first region A1.

Further, during the transfer process of the light-emitting elements 30, the buffer part 22 and the sacrificial part 21 are transferred together with the light-emitting elements 30, and then the sacrificial part 21 needs to be etched away, thereby satisfying the independent requirements of different light-emitting elements 30. On this basis, in the embodiment of the present application, the thickness of the sacrificial part 21 is configured to be smaller, which is conducive to reducing the corresponding etching difficulty when the sacrificial part 21 is subsequently removed, thereby ensuring relatively strong practicability.

It is to be noted that after the light-emitting elements 30 are transferred, in an embodiment, only the sacrificial part 21 in the sacrificial protective layer 20 may be removed, that is, the buffer part 22 does not need to be etched together with the sacrificial part 21. Alternatively, the sacrificial part 21 and the buffer part 22 may be etched simultaneously. In this case, since the thickness of the buffer part 22 is greater than the thickness of the sacrificial part 21, when the sacrificial part 21 is etched away, the buffer part 22 still retains part of the structure in contact with the light-emitting element 30. Further, since part of the structure of the buffer part 22 is etched away, the thickness corresponding to part of the structure that remains in the buffer part 22 is less than the thickness of the buffer part in the related art so that the thickness dimension of the light-emitting structure formed by the light-emitting elements 30 and the buffer part 22 in the finally formed display device is reduced, which is conducive to the thin and light design of the display device.

In some embodiments, as shown in FIG. 5, the surface of the sacrificial part 21 facing the first substrate 10 and the surface of the buffer part 22 facing the first substrate 10 are coplanar, that is, the surface of the sacrificial part 21 facing the first substrate 10 and the surface of the buffer part 22 facing the first substrate 10 are located in the same plane.

In the embodiment of the present application, the surface of the sacrificial part 21 facing the first substrate 10 and the surface of the buffer part 22 facing the first substrate 10 may together form a complete plane facilitating the peeling off of the entire sacrificial protective layer 20 from the first substrate 10 during the transfer process of the light-emitting elements 30, thereby satisfying the transfer requirements of the light-emitting elements 30. Moreover, in an embodiment, after the light-emitting elements 30 are transferred, the sacrificial part 21 and the buffer part 22 may be etched simultaneously. On this basis, since the surface of the sacrificial part 21 and the surface of the buffer part 22 are coplanar, a surface of the sacrificial protective layer 20 facing away from the light-emitting element 30 is flat and complete, which is conducive to the entire surface etching process of the sacrificial protective layer 20 and reducing the etching difficulty corresponding to the sacrificial part 21.

It is to be noted that in the embodiment of the present application, although the entire surface of the sacrificial protective layer 20 may be etched, since the thickness of the sacrificial part 21 is less than the thickness of the buffer part 22, after the sacrificial part 21 is etched away, part structure of the buffer part 22 still remains and keeps fitting the light-emitting element 30. In this manner, the remaining part of the structure of the buffer part 22 can reduce the impact of the etching process corresponding to the sacrificial part 21 on the light-emitting element 30; at the same time, in the finally formed display device, the remaining part of the structure of the buffer part 22 can play a buffering and protecting role for the light-emitting element 30; moreover, since part of the structure of the buffer part 22 is etched away, the thickness corresponding to the final remaining part of the structure of the buffer part 22 is less than the thickness of the buffer part in the related art so that the thickness dimension of the display device is reduced, which is conducive to the thin and light design.

In some embodiments, as shown in FIG. 5, a surface of the sacrificial part 21 facing away from the first substrate 10 is parallel to a plane where the first substrate 10 is located.

The surface of the sacrificial part 21 facing the first substrate 10 may fit the first substrate 10. Therefore, the surface of the sacrificial part 21 facing the first substrate 10 may be parallel to the plane where the first substrate 10 is located. Further, in the embodiment of the present application, the surface of the sacrificial part 21 facing away from the first substrate 10 is parallel to the plane where the first substrate 10 is located so that the thickness of the sacrificial part 21 at each position can be consistent. Further, after the light-emitting elements 30 are transferred, during the etching and removal process of the sacrificial part 21, it is convenient to achieve uniform etching of the sacrificial part 21, thereby reducing the difficulty of removing the sacrificial part 21 and satisfying the independent requirements of different light-emitting elements 30.

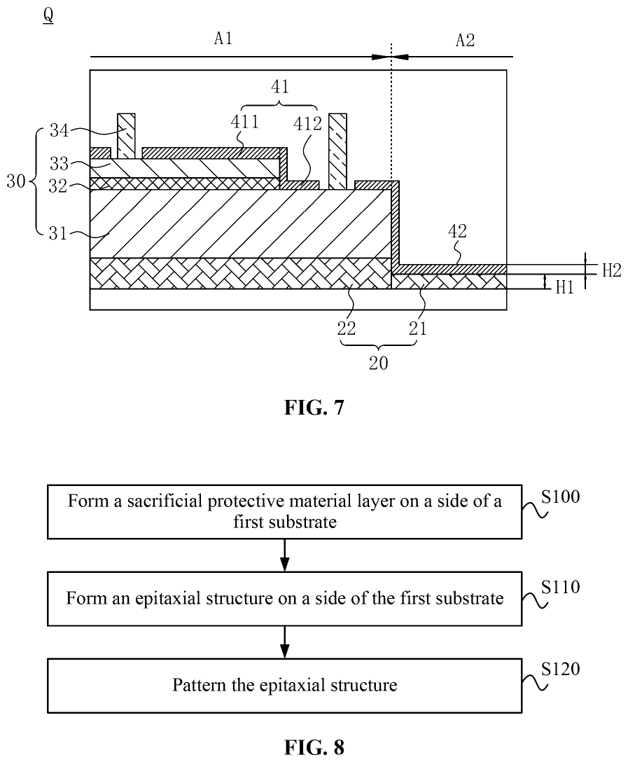

In some embodiments, referring to FIGS. 6 and 7, the light-emitting diode module 100 further includes an insulating layer 40, where the insulating layer 40 includes a first part 41 covering part of the structure of the light-emitting element 30 and a second part 42 connected to the first part 41 and located in the second region A2, and the sacrificial protective layer 20 is at least partially located between the first substrate 10 and the second part 42.

The insulating layer 40 includes an insulating material and can play an insulating and protecting role for the light-emitting element 30. In an embodiment, the insulating layer 40 includes an inorganic insulating material. The insulating layer 40 includes at least the first part 41 and the second part 42. The first part 41 is located in the first region A1, the second part 42 is located in the second region A2, and the second part 42 is connected to the first part 41. In an embodiment, the first part 41 and the second part 42 form an integral structure.

The first part 41 covers part of the structure of the light-emitting element 30. Specifically, the case where the light-emitting structure includes the first semiconductor layer 31, the light-emitting layer 32, and the second semiconductor layer 33 that are stacked in the direction away from the first substrate 10, and the first semiconductor layer 31 partially extends beyond the light-emitting layer 32 and the second semiconductor layer 33 in a direction parallel to the plane where the first substrate 10 is located is used as an example. The first part 41 includes a first sub-part 411 located on a side of the second semiconductor layer 33 facing away from the first substrate 10, the first sub-part 411 is provided with a through hole, and the electrode 34 for connecting the second semiconductor layer 33 may be disposed in the through hole. Moreover, the first part 41 further includes a second sub-part 412 located on a side of part of the structure of the first semiconductor layer 31 beyond the second semiconductor layer 33 and facing away from the first substrate 10, the second sub-part 412 is also provided with a through hole, and the electrode 34 may be disposed in the through hole and used for connecting the first semiconductor layer 31.

The second part 42 is located in the second region A2, and the sacrificial protective layer 20 is at least partially located between the first substrate 10 and the second part 42. Further, the sacrificial part 21 may be located between the first substrate 10 and the second part 42. In the related art, the second part 42 generally directly fits the first substrate 10. In this manner, during the transfer process of the light-emitting elements 30, the second part 42 is easily affected by laser irradiation, causing irregular fractures, affecting the structural reliability of the second part 42, and further easily affecting the insulation performance of the insulating layer 40, which is not conducive to the yield of the finally formed display device 300.

In the embodiment of the present application, since the sacrificial protective layer 20 is at least partially located between the first substrate 10 and the second part 42, during the transfer process of the light-emitting elements 30, at least part of the structure in the sacrificial protective layer 20 can help the second part 42 block part of the laser irradiation, thereby reducing the impact of the laser irradiation on the second part 42 and improving the entire structural reliability and insulation reliability of the insulating layer 40.

In some embodiments, the thickness of at least part of the structure of the sacrificial protective layer 20 in the second region A2 is H1, and the thickness of the second part 42 is H2, where H1 and H2 satisfy that ⅙≤H1/H2≤¼. In an embodiment, H1/H2 is ⅙, ⅕, 7/30, ¼, or the like.

It can be known from the preceding content that at least part of the structure of the sacrificial protective layer 20 located in the second region A2 can help the second part 42 block part of the laser irradiation and reduce the impact of the laser irradiation on the second part 42. On this basis, if the thickness H1 of at least part of the structure of the sacrificial protective layer 20 in the second region A2 is too small, then at least part of the structure of the sacrificial protective layer 20 in the second region A2 has an insufficient blocking and protection effect on the second part 42, and the second part 42 is still susceptible to the impact of the laser, easily causing irregular fractures of the second part 42. Therefore, in the embodiment of the present application, H1/H2 is configured to be no less than ⅙ so that at least part of the structure of the sacrificial protective layer 20 in the second region A2 can have a certain thickness dimension relative to the second part 42, thereby further reducing the impact of the laser irradiation on the second part 42 and improving the structural reliability of the insulating layer 40.

If H1 is too large, when at least part of the structure of the sacrificial protective layer 20 in the second region A2 is etched away after the light-emitting elements 30 are transferred, the thickness of the sacrificial protective layer 20 that needs to be etched away is too large. On this basis, if the etching accuracy is not high, the light-emitting element 30 is easily damaged, which is not conducive to the usage reliability of the light-emitting element 30. Therefore, in the embodiment of the present application, H1/H2 is configured to be no more than ¼ so that at least part of the structure of the sacrificial protective layer 20 in the second region A2 does not have an excessive thickness dimension, thereby reducing the adverse effect on the light-emitting elements 30 during the subsequent etching and removal of the sacrificial protective layer 20 and improving the structural reliability of the light-emitting elements 30 and the yield of the finally formed display device.

In some embodiments, the material of at least part of the structure of the sacrificial protective layer 20 in the second region A2 is different from the material of the second part 42.

After the light-emitting elements 30 are transferred, at least part of the structure of the sacrificial protective layer 20 in the second region A2 needs to be etched away, and the second part 42 of the insulating layer 40 also needs to be etched away, so as to satisfy the independent requirements of different light-emitting elements 30.

Further, in the embodiment of the present application, the material of at least part of the structure of the sacrificial protective layer 20 in the second region A2 is configured to be different from the material of the second part 42 so that when the sacrificial protective layer 20 and the second part 42 need to be etched away, it is necessary to use different etching media to etch away the sacrificial protective layer 20 and the second part 42 in different steps, which is conducive to improving the etching accuracy corresponding to the sacrificial protective layer 20 and the second part 42 and further improving the yield of the finally formed display device 300.

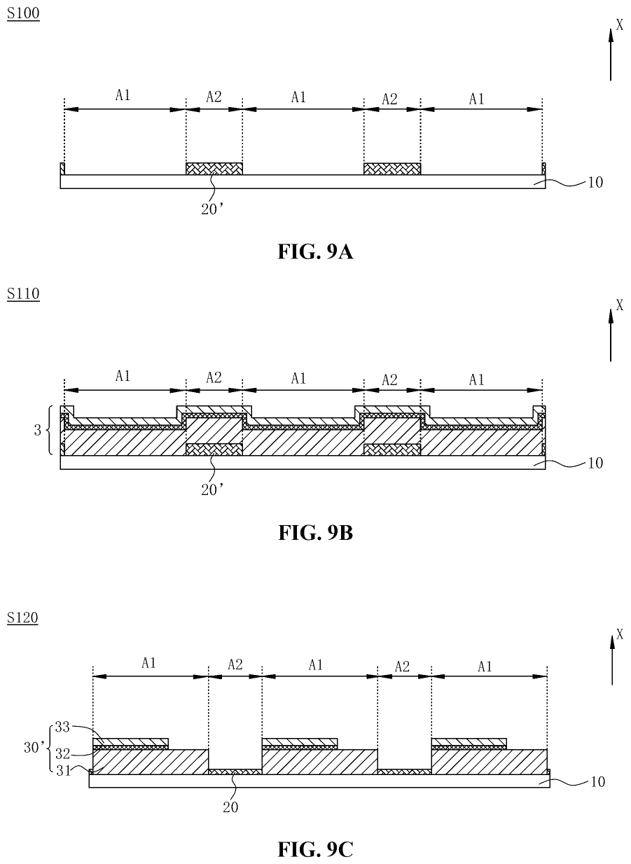

In a second aspect, referring to FIGS. 8 and 9, an embodiment of the present application provides a preparation method for a light-emitting diode module. The preparation method includes the steps described below.

In S100, a sacrificial protective material layer is formed on a side of a first substrate.

Referring to FIG. 9A, in step S100, the first substrate 10 has first regions A1 arranged at intervals and second regions A2, where a second region A2 is located between adjacent first regions A1, and a sacrificial protective material layer 20′ is at least partially located in the second region A2. The first region A1 corresponds to the region corresponding to the subsequently formed light-emitting element. The sacrificial protective material layer 20′ is used for subsequently forming the sacrificial protective layer. Depending on actual requirements, the structure of the sacrificial protective material layer 20′ may be completely consistent with the structure of the sacrificial protective layer, or the sacrificial protective layer may include only part of the structure of the sacrificial protective material layer 20′.

In S110, an epitaxial structure is formed on a side of the first substrate.

Referring to FIG. 9B, in step S110, an epitaxial structure 3 covers the first regions A1 and the second regions A2. Epitaxy refers to the technology of growing new crystals on the first substrate 10 to make semiconductor layers during the manufacturing process of a semiconductor device.

The epitaxial structure 3 may include multiple stacked film structures. The multiple film structures may be used for subsequently forming the light-emitting elements. Each film structure in the epitaxial structure 3 may be a full-surface structure and may cover both the first regions A1 and the second regions A2.

In S120, the epitaxial structure is patterned.

Referring to FIG. 9C, in step S120, the epitaxial structure is patterned so that the structure of the epitaxial structure in the second region A2 is etched away, thereby forming a light-emitting module 30′ in the first region A1 and forming the sacrificial protective layer 20 at least partially located in the second region A2. The light-emitting module 30′ includes part of the film structures of the light-emitting element. Specifically, the light-emitting module 30′ may include the first semiconductor layer 31, the light-emitting layer 32, the second semiconductor layer 33, and other film structures in the light-emitting element, but the light-emitting module 30′ does not include the electrode in the light-emitting element.

It is to be noted that multiple patterning manners exist. For example, the epitaxial structure 3 may be patterned by etching. Further, depending on the types of materials included in different layers in the epitaxial structure 3 and the sacrificial protective material layer 20′, different layers are etched using different etching media and in different processes, so as to satisfy the patterning requirements.

Further, in step S120, part of the structure in the sacrificial protective material layer 20′ may be etched so that the formed sacrificial protective layer 20 includes only part of the structure of the sacrificial protective material layer 20′. Alternatively, the sacrificial protective material layer 20′ may not be etched, that is, only the epitaxial structure 3 needs to be etched. In this case, the structure of the sacrificial protective material layer 20′ is completely consistent with the structure of the sacrificial protective layer 20.

In the embodiment of the present application, at least part of the structure of the sacrificial protective layer 20 exists in the second region A2 in the light-emitting diode module 100, and the sacrificial protective layer 20 is at least partially located in the second region A2 so that the first substrate 10 is provided with the film structure on the same side of the first region A1 and the second region A2, and the right-angled structure or similar right-angled structure is not formed at the junction of the first region A1 and the second region A2, which is conducive to reducing the risk of generating debris, improving the transfer accuracy corresponding to the subsequent transfer process of the light-emitting elements, and improving the preparation yield of the finally formed display device.

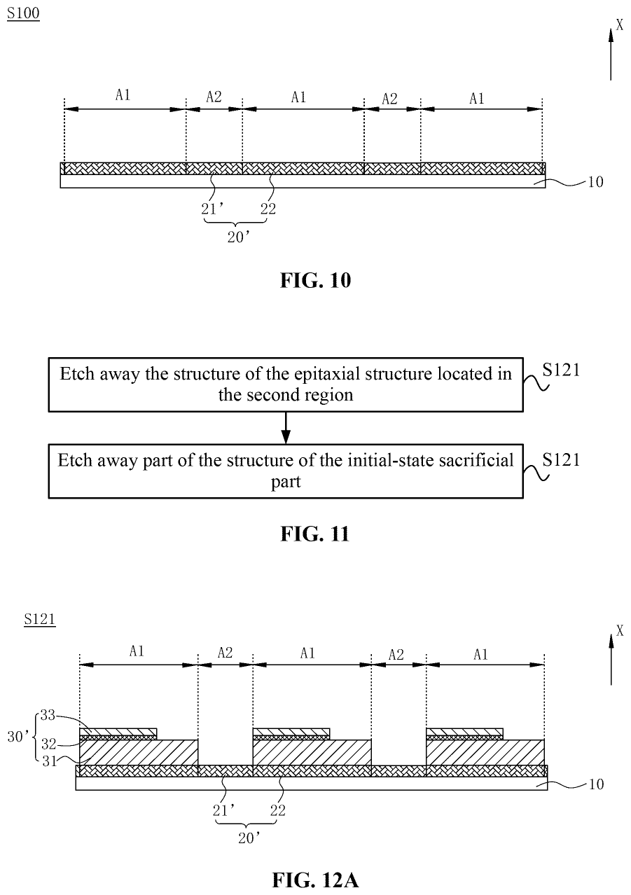

In some embodiments, referring to FIG. 10, in step S100, the sacrificial protective material layer 20′ includes the buffer part 22 located in the first region A1 and an initial-state sacrificial part 21′ located in the second region A2.

In the embodiment of the present application, the buffer part 22 and the initial-state sacrificial part 21′ may be formed together in the same preparation process, where the buffer part 22 and the initial-state sacrificial part 21′ may form an integral structure. In this manner, the sacrificial protective material layer 20′ may have a full-surface structure and cover both the first regions A1 and the second regions A2 of the first substrate 10, which is conducive to reducing the preparation difficulty of the sacrificial protective material layer 20′ and preparing a complete and flat surface for the preparation of the epitaxial structure in the subsequent step S110, thereby reducing the preparation difficulty in step S120 and reducing the risk of generating debris during the subsequent transfer of the light-emitting elements, which is conducive to improving the yield.

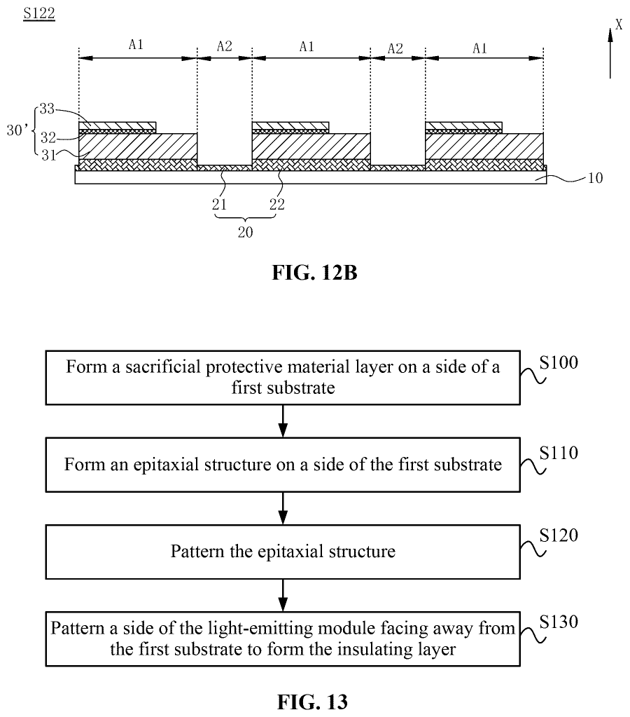

In some embodiments, referring to FIGS. 11 and 12, step S120 includes the steps described below.

In S121, the structure of the epitaxial structure located in the second region is etched away.

Referring to FIG. 12A, in step S121, the entire structure of the epitaxial structure in the second regions A2 need to be removed so that multiple formed light-emitting modules 30′ may be distributed in multiple first regions A1.

In an embodiment, part of the structure of the epitaxial structure located in the first region A1 also needs to be etched away. Specifically, the case where the light-emitting module 30′ includes the first semiconductor layer 31, the light-emitting layer 32, and the second semiconductor layer 33 that are stacked sequentially in the direction away from the first substrate 10 is used as an example. In the direction parallel to the plane where the first substrate 10 is located, the first semiconductor layer 31 needs to partially extend beyond the light-emitting layer 32 and the second semiconductor layer 33 so that the subsequently formed electrode 34 can be in contact with and connected to the first semiconductor layer 31. To achieve this structure, in this step, part of the material in the same layer as the light-emitting layer 32 in the first region A1 and part of the material in the same layer as the second semiconductor layer 33 in the first region A1 need to be etched away so that part of the structure in the first semiconductor layer 31 can be exposed relative to the second semiconductor layer 33 and the light-emitting layer 32, so as to satisfy the subsequent preparation requirements of the light-emitting elements.

It is to be noted that in this step, due to the difference between the material composition in the sacrificial protective material layer 20′ and the material composition between at least part of the films in the epitaxial structure, during the process of etching away the structure of the epitaxial structure 3 located in the second region A2 using the etching medium, the sacrificial protective material layer 20′ is not affected by etching, or the sacrificial protective material layer 20′ is less affected by etching, that is, in this step, the structure of the sacrificial protective material layer 20′ remains unchanged or changes to a relatively small extent.

In S122, part of the structure of the initial-state sacrificial part is etched away.

Referring to FIG. 12B, in step S122, only part of the structure of the initial-state sacrificial part is etched away, that is, the initial-state sacrificial part still retains part of the structure to form the sacrificial part 21 in the second region A2. Compared with the buffer part 22, the thickness of the sacrificial part 21 is generally smaller, thereby reducing the etching difficulty corresponding to the sacrificial part 21 after the subsequent transfer of the light-emitting elements.

In an embodiment, after the subsequent transfer of the light-emitting elements, the entire surface of the sacrificial part 21 and the buffer part 22 may be etched simultaneously, which is conducive to further reducing the etching difficulty. At the same time, since the thickness of the buffer part 22 is larger, after the sacrificial part 21 is etched, the buffer part 22 retains some structures to protect the light-emitting elements, thereby reducing the adverse effect of the etching process corresponding to the sacrificial part 21 on the light-emitting elements and improving the preparation yield.

In addition, during the subsequent transfer process of the light-emitting elements, the first substrate 10 has the light-emitting element and the buffer part 22 in the first region A1 and the sacrificial part 21 in the second region A2. This design is conducive to reducing the risk of generating debris during the transfer process, improving the accuracy corresponding to the transfer process, and improving the production yield of the finally formed display device.

Of course, in other embodiments, depending on actual requirements, step S122 may be canceled, that is, the initial-state sacrificial part 21′ is not etched. In this case, the sacrificial protective material layer 20′ is the sacrificial protective layer 20, the initial-state sacrificial part 21′ is the sacrificial part 21, and the thickness of the sacrificial part 21 may be consistent with the thickness of the buffer part 22.

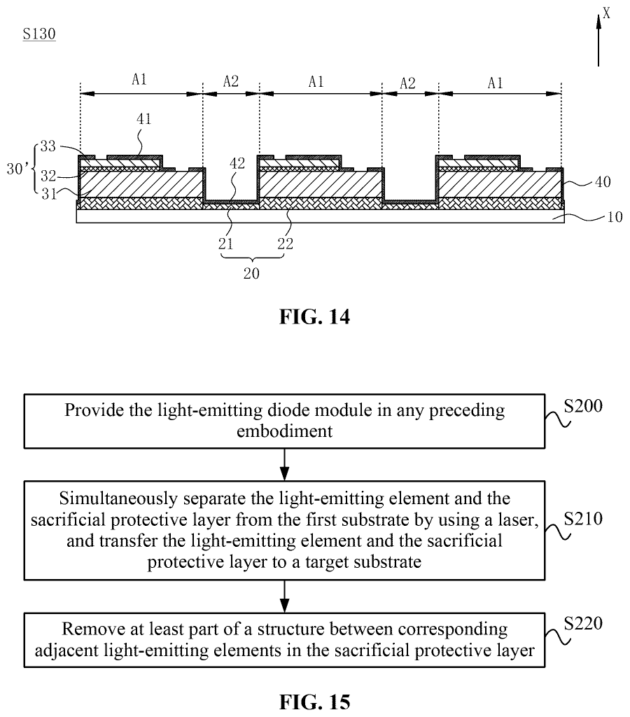

In some embodiments, referring to FIGS. 13 and 14, the preparation method further includes the step described below.

In S130, a side of the light-emitting module 30′ facing away from the first substrate 10 is patterned so as to form the insulating layer 40.

Referring to FIG. 14, in step S130, the insulating layer 40 includes the first part 41 covering part of the structure of the light-emitting module 30′ and the second part 42 connected to the first part 41 and located in the second region A2, and at least part of the sacrificial protective layer 20 is sandwiched between the second part 42 and the first substrate 10.

The first part 41 covers part of the structure of the light-emitting module 30′. Specifically, in conjunction with the preceding content, the light-emitting module 30′ may include the first semiconductor layer 31, the light-emitting layer 32, and the second semiconductor layer 33 that are stacked in the direction away from the first substrate 10, and the first semiconductor layer 31 partially extends beyond the light-emitting layer 32 and the second semiconductor layer 33 in the direction parallel to the plane where the first substrate 10 is located. The first part 41 includes the first sub-part located on the side of the second semiconductor layer 33 facing away from the first substrate 10, the first sub-part needs to be provided with a through hole, and the electrode for connecting the second semiconductor layer 33 may be prepared and formed in the through hole in the subsequent step. Moreover, the first part 41 further includes the second sub-part located on the side of part of the structure of the first semiconductor layer 31 beyond the second semiconductor layer 33 facing away from the first substrate 10, the second sub-part 412 also needs to be provided with a through hole, and the electrode for connecting the first semiconductor layer 31 may be prepared and formed in the through hole in the subsequent step.

The second part 42 is located in the second region A2, and the sacrificial protective layer 20 is at least partially located between the first substrate 10 and the second part 42. Further, the sacrificial part 21 may be located between the first substrate 10 and the second part 42. In the related art, the second part 42 generally directly fits the first substrate 10. In this manner, during the transfer process of the light-emitting elements 30, the second part 42 is easily affected by laser irradiation, causing irregular fractures, affecting the structural reliability of the second part 42, and further easily affecting the insulation performance of the insulating layer 40, which is not conducive to the yield of the finally formed display device 300.

In the embodiment of the present application, since the sacrificial protective layer 20 is at least partially located between the first substrate 10 and the second part 42, during the transfer process of the light-emitting elements 30, at least part of the structure in the sacrificial protective layer 20 can help the second part 42 block part of the laser irradiation, thereby reducing the impact of the laser irradiation on the second part 42 and improving the entire structural reliability and insulation reliability of the insulating layer 40.

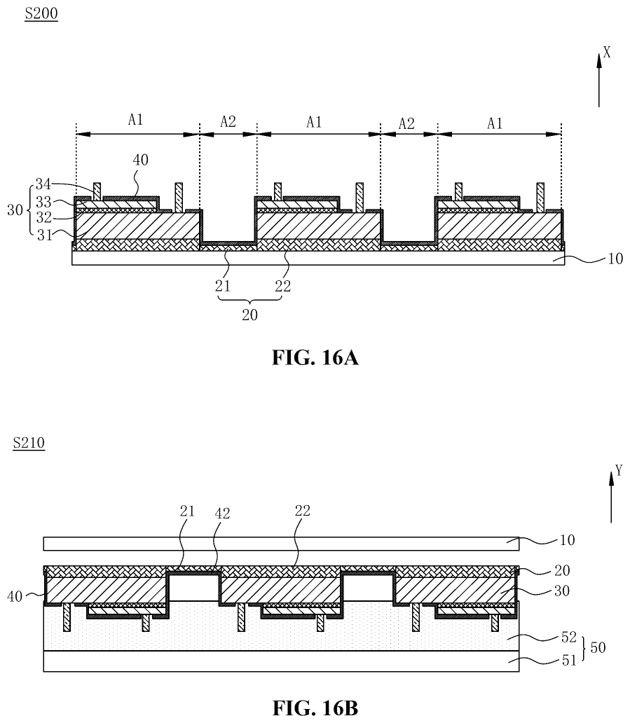

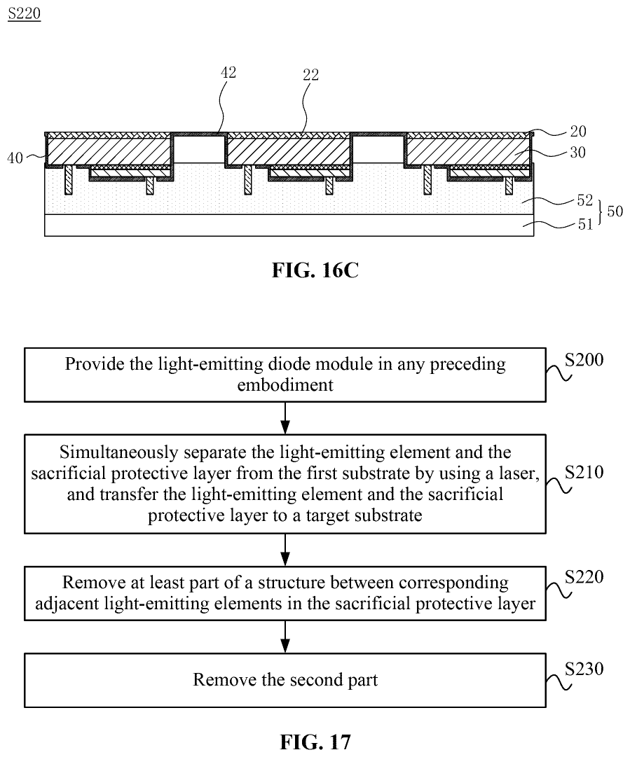

In a third aspect, referring to FIGS. 15 and 16, an embodiment of the present application provides a transfer method for the light-emitting element 30. The transfer method includes the steps described below.

In S200, the light-emitting diode module 100 in any preceding embodiment is provided.

Referring to FIG. 16A, in step S200, the light-emitting diode module 100 includes the first substrate 10, the sacrificial protective layer 20, and multiple light-emitting elements 30. The first substrate 10 has multiple first regions A1 arranged at intervals and second regions A2, where a second region A2 is located between adjacent first regions A1. The sacrificial protective layer 20 is located on a side of the first substrate 10 and at least partially located in the second region A2. The multiple light-emitting elements 30 are disposed in the multiple first regions A1 and located on the same side of the first substrate 10 as the sacrificial protective layer 20.

In S210, the light-emitting element and the sacrificial protective layer are simultaneously separated from the first substrate by using a laser, and the light-emitting element and the sacrificial protective layer are transferred to a target substrate.

Referring to FIG. 16B, in step S210, the laser may irradiate the side of the first substrate 10 facing away from the light-emitting element 30, and by the laser irradiation, the light-emitting element 30 and the sacrificial protective layer 20 are simultaneously separated from the first substrate 10 and transferred to a target substrate 50. The target substrate 50 may be used together with the light-emitting elements 30 to form a display panel.

In addition, since the light-emitting diode module has at least part of the structures of the light-emitting element 30 and the sacrificial protective layer in the first region and the second region, respectively and the light-emitting element 30 and the sacrificial protective layer jointly cover the first substrate 10, the probability of generating debris during the laser irradiation process is reduced, which is conducive to improving the transfer accuracy.

In S220, at least part of a structure between corresponding adjacent light-emitting elements in the sacrificial protective layer is removed.

Referring to FIG. 16C, in step S220, the structure between adjacent light-emitting elements 30 in the sacrificial protective layer 20 needs to be etched away, so as to achieve mutual independence between different light-emitting elements 30.

It is to be noted that a pickling step is further included between step S210 and step S220, where the pickling step is to clean and remove some metal ions generated due to the laser irradiation in step S210.

In some embodiments, as shown in FIG. 16B, in the light-emitting diode module 100, the sacrificial protective layer 20 includes the sacrificial part 21 located in the second region A2, the light-emitting diode module 100 further includes the insulating layer 40, and the insulating layer 40 includes the second part 42 covering a side of the sacrificial part 21 facing away from the first substrate 10.

The insulating layer 40 includes an insulating material and can play an insulating and protecting role for the light-emitting element 30. The insulating layer 40 includes the second part 42, and the second part 42 is located in the second region A2. Further, the sacrificial part 21 in the sacrificial protective layer 20 is located between the first substrate 10 and the second part 42.

In step S210, the laser irradiates the first substrate 10 from the sacrificial part 21 and a side of the first substrate 10 facing away from the second part 42. In this case, the sacrificial part 21 can help the second part 42 block part of the laser irradiation, In this manner, the impact of the laser irradiation on the second part 42 is reduced, the risk of irregular fractures of the second part 42 is reduced, and the entire structural reliability and insulation reliability of the insulating layer 40 are improved.

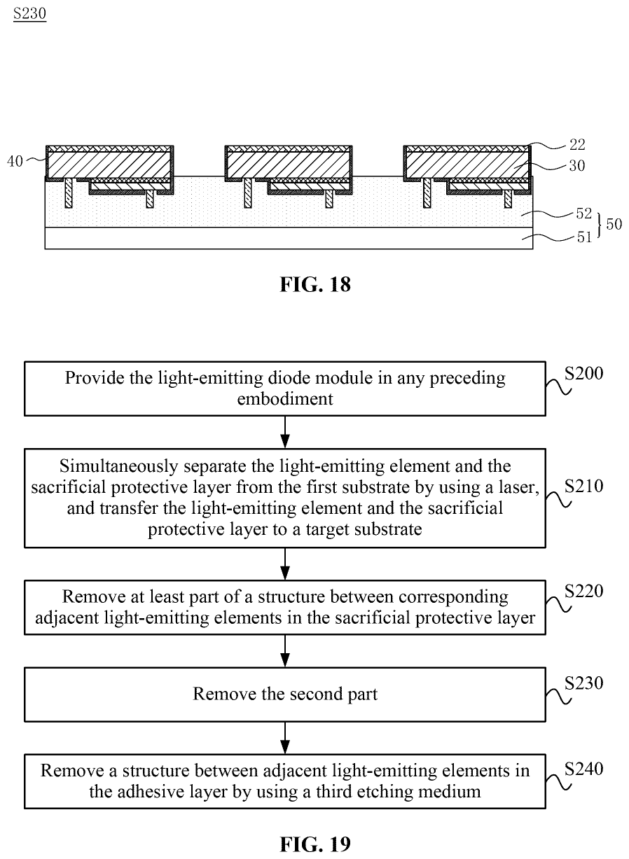

In some embodiments, referring to FIGS. 17 and 18, the transfer method further includes the step described below.

In S230, the second part 42 is removed.

Referring to FIG. 18, in step S230, adjacent light-emitting elements 30 can be separated from each other by removing the second part so that no other structures between adjacent light-emitting elements 30 for connecting different light-emitting elements 30 exist, which is conducive to achieving relative independence between different light-emitting elements 30, reducing the risk of external stress being transmitted to different light-emitting elements 30 through the second part during the subsequent usage of the display device, and improving the structural reliability corresponding to the light-emitting elements 30.

In some embodiments, the sacrificial part 21 and the second part 42 include different materials. In step S220, a first etching medium is used to remove the sacrificial part 21. In step S230, a second etching medium is used to remove the second part 42. At least part of the materials in the first etching medium and the second etching medium are different.

Since the sacrificial part 21 and the second part 42 include different materials, when the sacrificial part 21 and the second part 42 are removed, different etching media need to be separately used for etching removal. The first etching medium is used for etching away the sacrificial part 21, and the second etching medium is used for etching away the second part 42. In the case where the sacrificial protective layer 20 includes the buffer part 22, the first etching medium may simultaneously etch the buffer part 22 and the sacrificial part 21. In an embodiment, the first etching medium may include at least one of chlorine gas or boron trichloride, and the second etching medium may include at least one of oxygen or carbon tetrafluoride.

In the embodiment of the present application, since the sacrificial part 21 and the second part 42 include different materials, the first etching medium and the second etching medium with different materials need to be used to etch away the sacrificial part 21 and the second part 42, respectively. In this manner, the etching and removal of the sacrificial part 21 do not impose too much impact on the insulating layer 40, thereby reducing the risk of the insulating layer 40 being damaged by etching during the etching of the sacrificial part 21 and improving the structural reliability of the insulating layer 40.

In some embodiments, the target substrate 50 includes a second substrate 51 and an adhesive layer 52 located on a side of the second substrate 51 facing the light-emitting element 30, and the adhesive layer 52 and the sacrificial part 21 include different materials. The second substrate 51 is used for supporting the light-emitting elements 30 transferred to the target substrate 50. The adhesive layer 52 is located on a side of the second substrate 51 and may have a full-surface structure. The light-emitting elements 30 transferred to the target substrate 50 may be in direct contact with the adhesive layer 52. The adhesive layer 52 has a certain degree of viscosity and deformability. The adhesive layer 52 can help fix the relative positions between the second substrate 51 and the light-emitting elements 30.

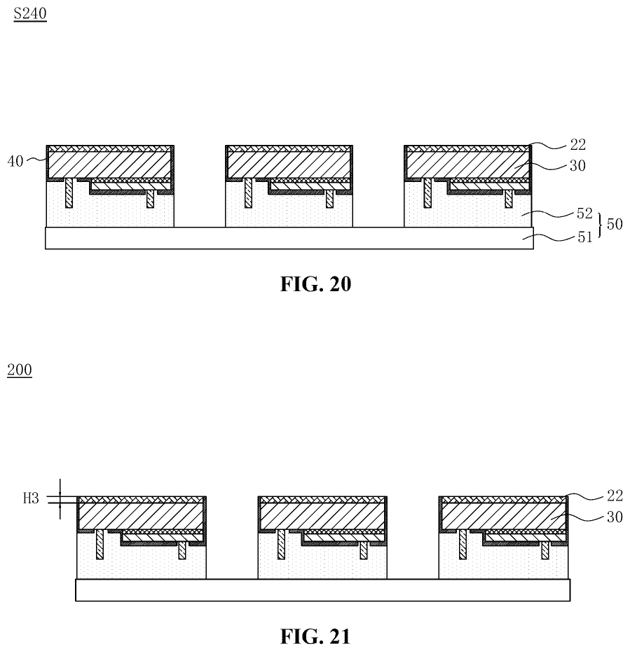

Further, referring to FIGS. 19 and 20, the transfer method further includes the step described below.

In S240, a structure between adjacent light-emitting elements 30 in the adhesive layer 52 is removed by using a third etching medium.

In step S240, since the adhesive layer 52 and the sacrificial part include different materials, at least part of the materials in the third etching medium used for etching the adhesive layer 52 and the first etching medium used for etching the sacrificial part 21 are different. In an embodiment, the adhesive layer 52 and the second part may include different materials so that at least part of the materials in the third etching medium and the second etching medium are different.

In the embodiment of the present application, since the sacrificial part and the adhesive layer 52 include different materials, the first etching medium and the third etching medium with different materials need to be used to etch away the sacrificial part and the adhesive layer 52, respectively. In this manner, the etching and removal of the sacrificial part do not impose too much impact on the adhesive layer 52, thereby reducing the risk of the adhesive layer 52 being damaged by etching during the etching of the sacrificial part and improving the structural reliability of the adhesive layer 52.

In some embodiments, the target substrate 50 includes the second substrate 51 and the adhesive layer 52 located on the side of the second substrate 51 facing the light-emitting element 30. As shown in FIG. 16B, in step S210, the second part 42 is spaced apart from the adhesive layer 52 in the thickness direction X of the first substrate 10.

Based on the preceding content, it can be seen that in step S210, the laser may irradiate the first substrate 10 from the sacrificial part 21 and the side of the first substrate 10 facing away from the second part 42 to separate the light-emitting elements 30, the sacrificial part 21, and the second part 42 from the first substrate 10. Further, the light-emitting elements 30 transferred to the target substrate 50 may be in direct contact with the adhesive layer 52, and the adhesive layer 52 can help fix the relative positions between the second substrate 51 and the light-emitting elements 30.

On this basis, in the embodiment of the present application, the second part 42 is spaced apart from the adhesive layer 52, thereby reducing the impact of the second part 42 on the adhesive layer 52 during the transfer process and reducing the risk of deformation of the adhesive layer 52. Moreover, during the subsequent etching and removal of the second part 42, the impact of the etching process on the adhesive layer 52 is reduced, and the structural reliability of the adhesive layer 52 is improved.

In a fourth aspect, referring to FIG. 21, an embodiment of the present application provides a display panel 200. The display panel 200 includes the light-emitting elements 30 transferred and formed by using the transfer method in any preceding embodiment.

In some embodiments, the display panel 200 includes the buffer part 22 fitting the light-emitting element 30, where in a thickness direction of the display panel 200, the thickness of the buffer part 22 is H3, where H3 satisfies that 0.2 μm≤H3≤1.8 μm.

Based on the preceding content, it can be seen that the buffer part 22 and the sacrificial part may form an integral structure and may be etched together by the same etching medium. On this basis, the thickness of the buffer part 22 is less than the thickness of the buffer part 22 in the display panel 200 in the related art. Specifically, the thickness H3 of the buffer part 22 prepared and formed using the transfer method provided in the embodiment of the present application is no greater than 1.8 μm, which is conducive to reducing the entire thickness dimension of the display panel 200 and achieving the thin and light design of the display panel 200.

Further, the buffer part 22 plays a buffering and protecting role for the light-emitting element 30. If the thickness of the buffer part 22 is too small, the buffering effect is insufficient and other problems may easily occur. Therefore, in the embodiment of the present application, the thickness H3 of the buffer part 22 is configured to be no less than 0.2 μm so that the buffer part 22 can play a certain buffering and protecting role for the light-emitting element 30, thereby improving the usage reliability of the display panel 200.

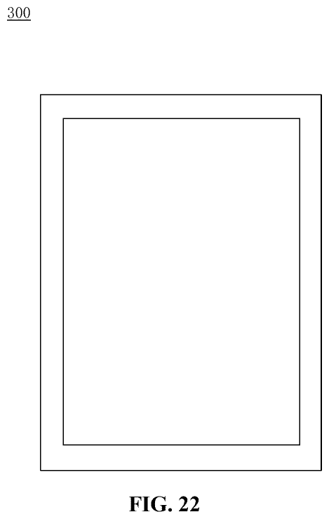

In a fifth aspect, referring to FIG. 22, an embodiment of the present application provides the display device 300. The display device 300 includes the display panel in any preceding embodiment.

It is to be noted that the display device provided in the embodiment of the present application has the beneficial effects of the display panel in any preceding embodiment. Reference may be made to the preceding description of the display panel and the transfer method. The details are not repeated in the embodiment of the present application.

Although the embodiments disclosed by the present application are as described above, the content thereof is merely embodiments for facilitating the understanding of the present application and is not intended to limit the present disclosure. Any technical person skilled in the art to which the present application pertains may make any modifications and variations in the implementation forms and details without departing from the spirit and scope disclosed by the present application, but the protection scope of the present application is still subject to the scope defined by the appended claims.

The preceding are only specific embodiments of the present application. Those skilled in the art may clearly understand that for ease and conciseness of description, for the replacement of other connection modes described above and the like, reference may be made to corresponding procedures in the preceding method embodiments and is not repeated here. It is to be understood that the scope of the present application is not limited to this. Those skilled in the art may easily conceive various equivalent modifications or substitutions within the technical scope of the present application. These modifications or substitutions should fall within the scope of the present application.

What is claimed is:

1. A light-emitting diode module, comprising:
a first substrate having a plurality of first regions arranged at intervals and a plurality of second regions, wherein a second region of the plurality of second regions is located between adjacent ones of the plurality of first regions;
a sacrificial protective layer located on a side of the first substrate and at least part of the sacrificial protective layer is located in the second region; and
a plurality of light-emitting elements disposed in the plurality of first regions and located on a same side of the first substrate as the sacrificial protective layer.

2. The light-emitting diode module of claim 1, wherein the sacrificial protective layer comprises a sacrificial part located in the second region and a buffer part located in a first region of the plurality of first regions, and a light-emitting element of the plurality of light-emitting elements is located on a side of the buffer part facing away from the first substrate.

3. The light-emitting diode module of claim 2, wherein the sacrificial part and the buffer part form an integral structure.

4. The light-emitting diode module of claim 2, wherein a dimension of the sacrificial part is less than a dimension of the buffer part in a thickness direction of the first substrate; and
wherein a surface of the sacrificial part facing the first substrate and a surface of the buffer part facing the first substrate are coplanar.

5. The light-emitting diode module of claim 2, wherein a surface of the sacrificial part facing away from the first substrate is parallel to a surface where the first substrate is located.

6. The light-emitting diode module of claim 1, further comprising an insulating layer, wherein the insulating layer comprises a first part covering part of a structure of a light-emitting element of the plurality of light-emitting elements and a second part connected to the first part and located in the second region, and at least part of the sacrificial protective layer is located between the first substrate and the second part.

7. The light-emitting diode module of claim 6, wherein a thickness of at least part of a structure of the sacrificial protective layer in the second region is H1, and a thickness of the second part is H2, wherein H1 and H2 satisfy that ⅙≤H1/H2≤¼.

8. The light-emitting diode module of claim 6, wherein material of at least part of a structure of the sacrificial protective layer in the second region is different from material of the second part.

9. A preparation method for a light-emitting diode module, comprising:
forming a sacrificial protective material layer on a side of a first substrate, wherein the first substrate has first regions arranged at intervals and second regions, wherein a second region of the second regions is located between adjacent ones of the first regions, and the sacrificial protective material layer is at least partially located in the second region;
forming an epitaxial structure on a side of the first substrate, wherein the epitaxial structure covers the first regions and the second regions; and
patterning the epitaxial structure to form a light-emitting module in a first region of the first regions and a sacrificial protective layer at least partially located in the second region, wherein the light-emitting module comprises part of film structures of a light-emitting element.

10. The preparation method of claim 9, wherein during forming the sacrificial protective material layer on the side of the first substrate, the sacrificial protective material layer comprises a buffer part located in the first region and an initial-state sacrificial part located in the second region.

11. The preparation method of claim 10, wherein patterning the epitaxial structure comprises:
etching away a structure of the epitaxial structure located in the second region to form the light-emitting module in the first region; and
etching away part of a structure of the initial-state sacrificial part to form a sacrificial part in the second region.

12. The preparation method of claim 9, further comprising:
patterning a side of the light-emitting module facing away from the first substrate to form an insulating layer, wherein the insulating layer comprises a first part covering part of a structure of the light-emitting module and a second part connected to the first part and located in the second region, and at least part of the sacrificial protective layer is sandwiched between the second part and the first substrate.

13. A transfer method for a light-emitting element, comprising:
providing a light-emitting diode module, wherein the light-emitting diode module comprises: a first substrate having a plurality of first regions arranged at intervals and a plurality of second regions, wherein a second region of the plurality of second regions is located between adjacent ones of the plurality of first regions; a sacrificial protective layer located on a side of the first substrate and at least part of the sacrificial protective layer is located in the second region; and a plurality of light-emitting elements disposed in the plurality of first regions and located on a same side of the first substrate as the sacrificial protective layer;
simultaneously separating the light-emitting element and the sacrificial protective layer from the first substrate by using a laser and transferring the light-emitting element and the sacrificial protective layer to a target substrate; and
removing at least part of a structure between corresponding adjacent light-emitting elements in the sacrificial protective layer.

14. The transfer method of claim 13, wherein the sacrificial protective layer in the light-emitting element module comprises a sacrificial part located in the second region and a buffer part located in a first region of the plurality of first regions; and
during removing the at least part of the structure between corresponding adjacent light-emitting elements in the sacrificial protective layer, at least part of a structure in the buffer part is removed together with the sacrificial part.

15. The transfer method of claim 13, wherein in the light-emitting diode module, the sacrificial protective layer comprises a sacrificial part located in a second region, the light-emitting diode module further comprises an insulating layer, and the insulating layer comprises a second part covering a side of the sacrificial part facing away from the first substrate; and
a laser is used to simultaneously separate the light-emitting element and the sacrificial part from the first substrate, and the laser irradiates the first substrate from the sacrificial part and a side of the first substrate facing away from the second part.

16. The transfer method of claim 15, further comprising:
removing the second part to separate adjacent light-emitting elements from each other; and
one of following is satisfied:
the sacrificial part and the second part comprise different materials;
during removing the at least part of the structure between corresponding adjacent light-emitting elements in the sacrificial protective layer, a first etching medium is used to remove the sacrificial part; and during removing the second part, a second etching medium is used to remove the second part, wherein at least part of materials in the first etching medium are different from the second etching medium; or
the target substrate comprises a second substrate and an adhesive layer located on a side of the second substrate facing the light-emitting element, and the adhesive layer comprise different materials from the sacrificial part; and during removing the at least part of the structure between corresponding adjacent light-emitting elements in the sacrificial protective layer, a first etching medium is used to remove the sacrificial part, wherein the transfer method further comprises removing a structure between adjacent light-emitting elements in the adhesive layer by using a third etching medium, wherein at least part of materials in the third etching medium are different from the first etching medium.

17. The transfer method of claim 15, wherein the target substrate comprises a second substrate and an adhesive layer located on a side of the second substrate facing the light-emitting element; and
during simultaneously separating the light-emitting element and the sacrificial protective layer from the first substrate by using the laser, the second part is spaced apart from the adhesive layer in a thickness direction of the first substrate.

18. A display panel, comprising the plurality of light-emitting elements transferred and formed by using the transfer method of claim 13.

19. The display panel of claim 18, comprising a buffer part fitting a light-emitting element of the plurality of light-emitting elements, wherein in a thickness direction of the display panel, a thickness of the buffer part is H3, wherein H3 satisfies that 0.2 μm≤H3≤1.8 μm.

20. A display device, comprising the display panel of claim 18.
